(19) United States
(12) Patent Application Publication
(10) Pub. No.: US 2012/0173941 A1
(43) Pub. Date: Jul. 5, 2012

(54) METHOD, SYSTEM AND PROCESSOR FOR LOADING LOGICAL DEVICES ONLINE

(75) Inventors: Bingbing TONG, Shenzhen (CN); Yusen LI, Shenzhen (CN); Lei SHI, Shenzhen (CN); Yongning CHEN, Shenzhen (CN)

(73) Assignee: CHENGDU HUAWEI SYMANTEC TECHNOLOGIES CO., LTD., Chengdu (CN)

(21) Appl. No.: 13/416,808

(22) Filed: Mar. 9, 2012

Related U.S. Application Data
(63) Continuation of application No. PCT/CN2010/076704, filed on Sep. 8, 2010.

(30) Foreign Application Priority Data
Sep. 10, 2009 (CN) 200910092903.6

(51) Int. Cl. G01R 31/3177; G06F 11/25

(52) U.S. Cl. 714/727; 714/E11.155

(57) ABSTRACT

A method, a system, and a processor for loading a logical device online are disclosed. The method for loading a logical device online includes receiving an online loading command; disabling a Joint Test Action Group (JTAG) link of a board on which the logical device is located through a bus between a processor and the logical device according to the online loading command, and enabling a link between an input/output (I/O) interface and a JTAG interface of the logical device through the bus according to the online loading command; and controlling the logical device through the bus so that the logical device is loaded online through the link between the I/O interface and the JTAG interface of the logical device. In this way, the logical device is loaded online without occupying any I/O interface or requiring addition of any I/O device.

### CROSS-REFERENCE TO RELATED APPLICATIONS

This application is a continuation of International Application PCT/CN2010/076704, filed on Sep. 8, 2010, which claims priority to Chinese Patent Application No. 200910092903.6, filed on Sep. 10, 2009, which is hereby incorporated by reference in its entirety.

### FIELD OF THE INVENTION

The present invention relates to communication technologies, and in particular, to a method, a system, and a processor for loading logical devices online.

### BACKGROUND OF THE INVENTION

A Complex Programmable Logical Device (CPLD) is an electrically erasable logical device, whose program logics still work even when the device is powered off. The CPLD is widely applied on various boards currently available. In the prior art, a Joint Test Action Group (JTAG) link is used to download programs for the CPLD through an external programming device. However, that practice has defects. Due to complexity of board and service processing, sometimes the codes need to be changed because the source codes have problems or because the requirements have changed. In this case, codes in a logical device such as CPLD can be upgraded online, thereby enhancing upgradability and maintainability, and reducing maintenance costs. However, if the Central Processing Unit (CPU) is in the JTAG link, once the JTAG link starts working, the CPU of the board to be loaded enters the JTAG state, and it is impossible to load the CPLD online. When the entire system is composed of low-end devices and includes no external main control board, a JTAG loading wire is required for updating the CPLD of a board to be loaded. For shipped boards, if codes need to be updated in the subsequent process of using the board, the board needs to be returned to the factory for updating, or loaded by a specific engineer, which is costly.

Another loading mode in the prior art is to use a universal input (I)/output (O) interface of the CPU to load the CPLD online by simulating the JTAG; or an external programming device connects the JTAG loading wire to a JTAG socket to load the CPLD. However, in such a mode, the CPU uses the I/O interface to simulate the JTAG so that the I/O interface has to be occupied. Moreover, for some plug-in cards without a CPU, the connectors of the plug-in cards are fixed and have no I/O interface connected to the motherboard CPU, and the CPLD cannot be loaded online with the foregoing method. Another method in the prior art is to add an I/O device on the CPU of the board to be loaded, and load the CPLD by simulating the JTAG to overcome the impossibility of online loading caused by lack of an I/O interface on the universal CPU. However, with the I/O device being added, a programmable device is added to the board, and the added I/O device needs to be loaded, which increases costs of production and maintenance.

In the process of developing the present invention, the inventor finds at least the following problems in the prior art: With a JTAG link being used for loading, the loading cannot be performed online; if the universal I/O interface of the CPU is used to load the CPLD by simulating the JTAG, the I/O interface of the CPU must be occupied, and the loading is impractical if the board has no CPU; and the method of adding an I/O device to load the CPLD by simulating the JTAG increases costs of production and maintenance.

### SUMMARY OF THE INVENTION

An embodiment of the present invention provides a method, a system, and a processor for loading logical devices online so that the logical devices can be loaded online without occupying any I/O interface, and so that logical devices on a board without a CPU but with a bus interface can be loaded online.

An embodiment of the present invention provides a method for loading a logical device online, including:

receiving an online loading command;

disabling a JTAG link of a board on which the logical device is located through a bus between a processor and the logical device according to the online loading command, and

enabling a link between an I/O interface and a JTAG interface of the logical device through the bus according to the online loading command; and controlling the logical device through the bus so that the logical device is loaded online through the link between the I/O interface and the JTAG interface of the logical device.

An embodiment of the present invention provides a processor, including:

a receiving module, configured to receive an online loading command;

an enabling/disabling module, configured to disable a JTAG link of a board on which a logical device is located through a bus between the processor and the logical device according to the online loading command received by the receiving module, and enable a link between an I/O interface and a JTAG interface of the logical device; and

a control module, configured to control the logical device through the bus so that the logical device is loaded online through the link between the I/O interface and the JTAG interface of the logical device.

An embodiment of the present invention provides a system for loading a logical device online, including:

a processor, configured to: receive an online loading command, disable a JTAG link of a board on which the logical device is located through a bus between the processor and the logical device according to the online loading command, and enable a link between an I/O interface and a JTAG interface of the logical device; and control the logical device through the bus so that the logical device is loaded online through the link between the I/O interface and the JTAG interface of the logical device; and

a logical device, configured to be loaded online through the link between the I/O interface and the JTAG interface of the logical device under control of the processor.

In the embodiments of the present invention, after receiving an online loading command, the processor disables the JTAG link of a board on which the logical device is located through a bus between the processor and the logical device, and enables the link between the I/O interface and the JTAG interface of the logical device; and the logical device is loaded online through the link between the I/O interface and the JTAG interface of the logical device. In this way, the logical device is loaded online without occupying any I/O interface or requiring addition of any I/O device. The embodiments of the present invention are also applicable to loading logical devices online on a board that includes no processor but includes a bus interface.

### BRIEF DESCRIPTION OF THE DRAWINGS

To illustrate the technical solution of the present invention or the prior art more clearly, the following paragraphs outline the accompanying drawings. It would be apparent to one of ordinary skill in the art that the accompanying drawings outlined below are illustrative rather than exhaustive, and that persons of ordinary skill in the art can derive other drawings from them without any creative effort.

FIG. 1 is a flowchart of a method for loading a logical device online according to an embodiment of the present invention;

FIG. 2 is a flowchart of a method for loading a logical device online according to another embodiment of the present invention;

FIG. 3 is a schematic diagram of an application scenario according to an embodiment of the present invention;

FIG. 4 is a schematic diagram of an application scenario according to another embodiment of the present invention;

FIG. 5 is a schematic structure diagram of a processor according to an embodiment of the present invention;

FIG. 6 is a schematic structure diagram of a processor according to another embodiment of the present invention;

FIG. 7 is a schematic structure diagram of a system for loading a logical device online according to an embodiment of the present invention;

FIG. 8 is a schematic structure diagram of a system for loading a logical device online according to another embodiment of the present invention;

FIG. 9 is a schematic structure diagram of a system for loading a logical device online according to a preferred embodiment of the present invention;

FIG. 10 is a schematic structure diagram of a system for loading a logical device online according to another preferred embodiment of the present invention; and

FIG. 11 is a schematic structure diagram of a system for loading a logical device online according to another preferred embodiment of the present invention.

### DETAILED DESCRIPTION OF THE EMBODIMENTS

The following detailed description is given in conjunction with the accompanying drawings in order to provide a thorough understanding of the present invention. The drawings and the detailed description are merely representative of particular embodiments of the present invention rather than all embodiments. All other embodiments, which can be derived by those skilled in the art from the embodiments given herein without any creative effort, shall fall within the protective scope of the present invention.

A method for loading a logical device online is disclosed herein. The I/O interface of the logical device is connected to the JTAG interface of the logical device, and the processor is connected to the bus interface of the logical device through a bus, and the bus controls the logical device to load the logical device online. In the embodiments of the present invention, the bus may be any bus between the processor and the logical device, for example, a control bus.

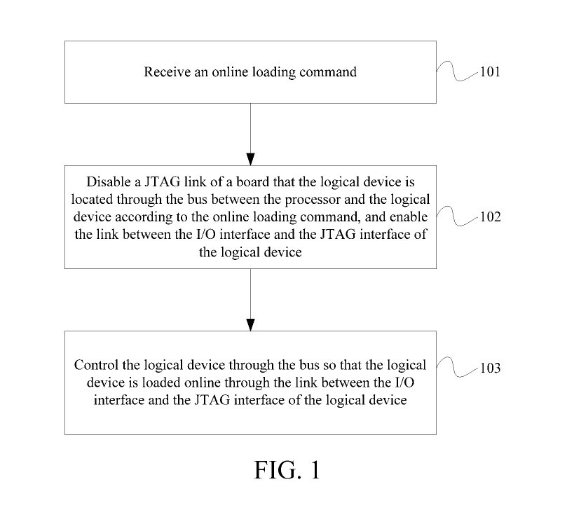

FIG. 1 is a flowchart of a method for loading a logical device online according to an embodiment of the present invention. As shown in FIG. 1, the method provided in this embodiment includes the following steps:

Step 101: Receive an online loading command.

Step 102: Disable a JTAG link of a board on which the logical device is located through the bus between the processor and the logical device according to the online loading command, and enable the link between the I/O interface and the JTAG interface of the logical device. Specifically, disable the first buffer on the JTAG link of the board on which the logical device is located through the bus, and enable the second buffer on the link between the I/O interface and the JTAG interface of the logical device.

Step 103: Control the logical device through the bus so that the logical device is loaded online through the link between the I/O interface and the JTAG interface of the logical device.

In this embodiment, the logical device is a programmable logical device such as CPLD, and the entity that performs the steps in this embodiment may be a processor such as CPU.

In the embodiment described above, after receiving an online loading command, the processor disables the JTAG link of a board on which the logical device is located through a bus between the processor and the logical device, and enables the link between the I/O interface and the JTAG interface of the logical device; and the logical device is loaded online through the link between the I/O interface and the JTAG interface of the logical device. In this way, the logical device is loaded online without occupying any I/O interface or requiring addition of any I/O device.

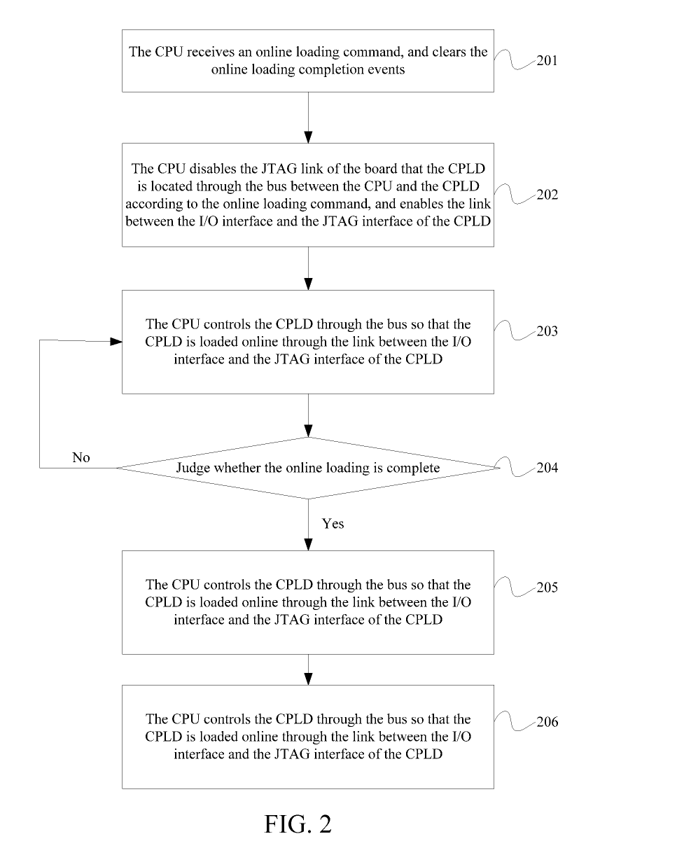

FIG. 2 is a flowchart of a method for loading a logical device online according to another embodiment of the present invention. In this embodiment, it is assumed that the processor is a CPU and the logical device is a CPLD. As shown in FIG. 2, the method provided in this embodiment includes the following steps:

Step 201: The CPU receives an online loading command, and clears the online loading completion events.

Step 202: The CPU disables the JTAG link of the board that the CPLD is located through the bus between the CPU and the CPLD according to the online loading command, and enables the link between the I/O interface and the JTAG interface of the CPLD. Specifically, the CPU disables the first buffer on the JTAG link of the board that the CPLD is located through the bus, and enables the second buffer on the link between the I/O interface and the JTAG interface of the CPLD. In this embodiment, the JTAG link includes the CPLD, and optionally, includes at least one JTAG device. If the JTAG link includes the CPLD only, the first buffer is located between the JTAG interface of the CPLD and the external loading device; if the JTAG link includes the CPLD and at least one JTAG device, the first buffer is located between the JTAG interface and the JTAG device of the CPLD.

In this embodiment, after the board is processed, the board may connect the JTAG loading wire to the JTAG socket, and an external loading device loads the CPLD initially. The JTAG loading wire may be a JTAG download cable. After the first loading, the logical functions of the CPLD run normally. By default, the register of the CPLD exercises control to enable the JTAG link of the board that the CPLD is located, and disable the link between the I/O interface and the JTAG interface of the CPLD.

After receiving the online loading command, the CPU disables the JTAG link of the board that includes the CPLD through the bus between the CPU and the CPLD, and enables the link between the I/O interface and the JTAG interface of the CPLD.

Step 203: The CPU controls the CPLD through the bus so that the CPLD is loaded online through the link between the I/O interface and the JTAG interface of the CPLD.

After the link between the I/O interface and the JTAG interface of the CPLD is enabled, the CPU controls the CPLD through the bus so that the CPLD is loaded online through the link between the I/O interface and the JTAG interface of the CPLD. In this case, the logical functions of the CPLD run properly, and no impact is caused onto other functions of the board that includes the CPLD.

Step 204: Judge whether the online loading is complete. If the online loading is complete, go to step 205; if the online loading is not complete, return to step 203.

Step 205: The CPU enables the JTAG link of the board that the CPLD is located through the bus, and disables the link between the I/O interface and the JTAG interface of the CPLD; and records an online loading completion event. Specifically, the CPU enables the first buffer on the JTAG link of the board that the CPLD is located through the bus, and disables the second buffer on the link between the I/O interface and the JTAG interface of the CPLD. At this time, the new program has been loaded onto an on-chip flash memory of the CPLD, and the CPU can control to re-power on the board that the CPLD is located at any proper time and update the logics of the CPLD.

In this embodiment, upon completion of the online loading, the CPU records the online loading completion event. The CPU clears the online loading completion events whenever it receives an online loading command. Therefore, steps 201-205 may repeat before the board is powered on again. The effective program is the program last loaded before the board is powered on again.

Step 206: The CPU controls to re-power on the board that includes the CPLD and update the logics of the CPLD through the bus.

In this embodiment, after the online loading is complete, the active logical functions of the CPLD are still the non-updated logical functions. At any proper time, through the bus between the CPU and the CPLD, the CPU may control to power on the board that the CPLD is located again and update the logics of the CPLD.

In the embodiment described above, after receiving an online loading command, the CPU disables the JTAG link of the board that the CPLD is located through the bus between the CPU and the CPLD, and enables the link between the I/O interface and the JTAG interface of the CPLD; and the CPLD is loaded online through the link between the I/O interface and the JTAG interface of the CPLD. In this way, the CPLD is loaded online without occupying any I/O interface or requiring addition of any I/O device. The method provided in the foregoing embodiment is also applicable to loading logical devices online on a board that includes no processor but includes a bus interface.

In the embodiments shown in FIG. 1 and FIG. 2, an implementation mode of “disabling the JTAG link of the board on which the logical device is located and enabling the link between the I/O interface and the JTAG interface of the logical device” is provided, and an implementation mode of “enabling the JTAG link of the board on which the logical device is located and disabling the link between the I/O interface and the JTAG interface of the logical device” is provided. However, the embodiments of present invention are not limited to that. A buffer may be used instead, and two channels in the buffer are connected to the foregoing two links; the processor controls the two channels of the buffer through the bus between the processor and the logical device to accomplish the purpose of “disabling the JTAG link of the board on which the logical device is located and enabling the link between the I/O interface and the JTAG interface of the logical device” and the purpose of “enabling the JTAG link of the board on which the logical device is located and disabling the link between the I/O interface and the JTAG interface of the logical device”. The embodiments of the present invention do not restrict the implementation mode of “disabling the JTAG link of the board on which the logical device is located and enabling the link between the I/O interface and the JTAG interface of the logical device” or restrict the implementation mode of “enabling the JTAG link of the board on which the logical device is located and disabling the link between the I/O interface and the JTAG interface of the logical device”. Any modes that accomplish the foregoing purposes shall fall within the protection scope of the present invention.

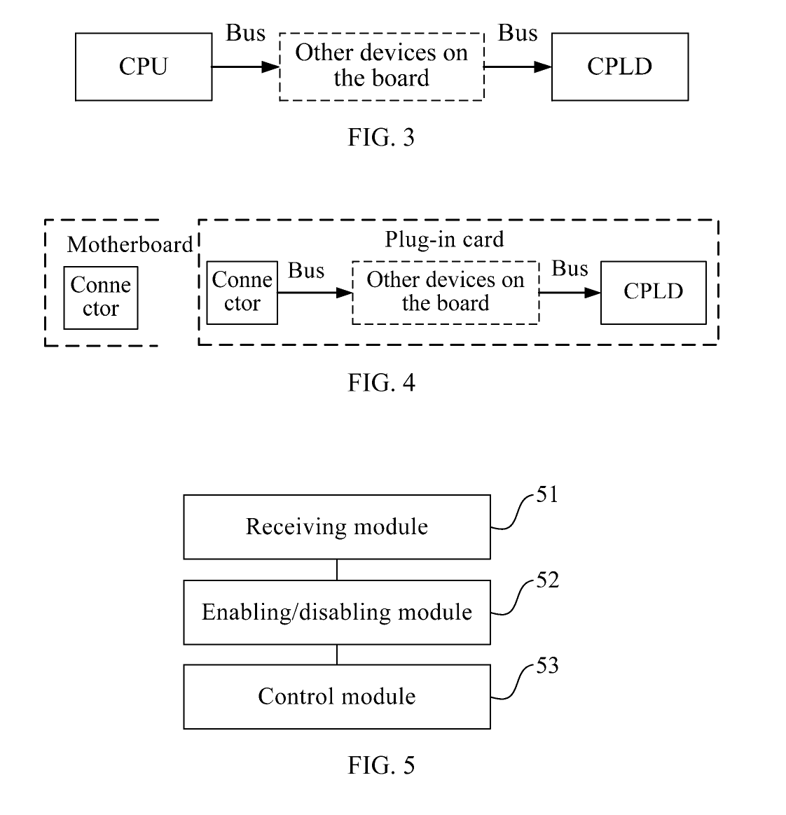

The method for loading a logical device online in this embodiment is applicable to loading a CPLD on a board that includes a CPU. FIG. 3 is a schematic diagram of an application scenario according to an embodiment of the present invention. In FIG. 3, the CPU is connected with the CPLD through a bus, and the bus is a control bus or another type of bus. The method for loading a logical device online in this embodiment does not cause any impact on the normal work of the CPLD or any other device on the board. Therefore, the CPU may be connected with the CPLD directly through the bus, or connected with the CPLD through other devices. In the scenario shown in FIG. 3, so long as a bus of the CPU is connected to the CPLD, the method provided in the embodiment shown in FIG. 1 or FIG. 2 is applicable to loading the CPLD online without occupying any I/O interface of the CPU.

The method for loading a logical device online in this embodiment is also applicable to loading a CPLD online on a board (such as a plug-in card) that includes no CPU but includes a bus interface. FIG. 4 is a schematic diagram of an application scenario according to another embodiment of the present invention. In FIG. 4, the plug-in card includes the CPLD that needs to be loaded online, but includes no CPU, and no universal I/O interface is available on the motherboard for connecting to the plug-in card through a connector. Normally, the CPLD has a bus connected to the CPU of the motherboard. Therefore, the method provided in the embodiment shown in FIG. 1 or FIG. 2 is applicable to loading the CPLD online without occupying any I/O interface of the CPU. The bus may be a control bus or any other type of bus. Here the CPLD may be connected with the CPU of the motherboard directly or through other devices.

Persons of ordinary skill in the art should understand that all or a part of the steps of the method according to the embodiments of the present invention may be implemented by a program instructing relevant hardware. The program may be stored in computer readable storage media. When the program runs, the program executes steps of the method specified in any embodiment of the present invention. The storage media may be any media capable of storing program codes, such as Read-Only Memory (ROM), Random Access Memory (RAM), magnetic disk, or CD-ROM.

FIG. 5 is a schematic structure diagram of a processor according to an embodiment of the present invention. In this embodiment, the processor is a CPU, or a part of the CPU, and implements the process shown in FIG. 1. As shown in FIG. 5, the processor includes a receiving module 51, an enabling/disabling module 52, and a control module 53.

The receiving module 51 receives an online loading command; the enabling/disabling module 52 disables a JTAG link of a board on which the logical device is located through the bus between the processor and the logical device according to the online loading command received by the receiving module 51, and enables the link between the I/O interface and the JTAG interface of the logical device. The control module 53 controls the logical device through the bus so that the logical device is loaded online through the link between the I/O interface and the JTAG interface of the logical device.

The logical device in this embodiment may be a programmable logical device such as CPLD.

In the embodiment described above, after the receiving module 51 receives an online loading command, the enabling/disabling module 52 disables the JTAG link of the board on which the logical device is located through the bus between the processor and the logical device, and enables the link between the I/O interface and the JTAG interface of the logical device; and the control module 53 controls the logical device through the bus so that the logical device is loaded online through the link between the I/O interface and the JTAG interface of the logical device. In this way, the logical device is loaded online without occupying any I/O interface or requiring addition of any I/O device.

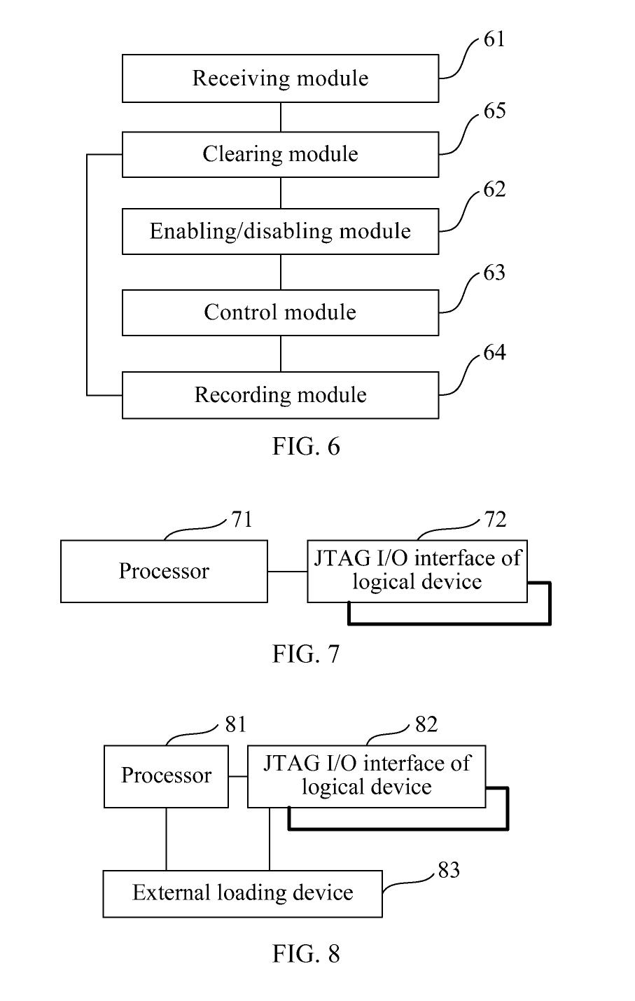

FIG. 6 is a schematic structure diagram of a processor according to another embodiment of the present invention. In this embodiment, the processor is a CPU, or a part of the CPU, and implements the process shown in FIG. 1 or FIG. 2. As shown in FIG. 6, the processor includes a receiving module 61, an enabling/disabling module 62, a control module 63, a recording module 64, and a clearing module 65.

The receiving module 61 receives an online loading command. The enabling/disabling module 62 disables a JTAG link of a board on which the logical device is located through the bus between the processor and the logical device according to the online loading command received by the receiving module 61, and enables the link between the I/O interface and the JTAG interface of the logical device. Specifically, the enabling/disabling module 62 disables the first buffer on the JTAG link of the board on which the logical device is located through the bus, and enables the second buffer on the link between the I/O interface and the JTAG interface of the logical device. In this embodiment, the JTAG link includes the foregoing logical device, and optionally, includes at least one JTAG device. If the JTAG link includes the logical device only, the first buffer is located between the JTAG interface of the logical device and the external loading device; if the JTAG link includes the logical device and at least one JTAG device, the first buffer is located between the JTAG interface and the JTAG device of the logical device.

The control module 63 controls the logical device through the bus so that the logical device is loaded online through the link between the I/O interface and the JTAG interface of the logical device.

In this embodiment, after the online loading is complete, the enabling/disabling module 62 may enable the JTAG link of the board on which the logical device is located through the bus, and disable the link between the I/O interface and the JTAG interface of the logical device. Specifically, after the online loading is complete, the enabling/disabling module 62 disables the second buffer on the link between the I/O interface and the JTAG interface of the logical device through the bus, and enables the first buffer on the JTAG link of the board on which the logical device is located.

Upon completion of the online loading, the control module 63 may control through the bus to power on the board on which the logical device is located and update the logics of the logical device.

The recording module 64 records an online loading completion event upon completion of the online loading; and the clearing module 65 clears the online loading completion event recorded by the recording module 64 after the receiving module 61 receives an online loading command. In this embodiment, upon completion of the online loading, the recording module 64 records the online loading completion event; the clearing module 65 clears the online loading completion event whenever the receiving module 61 receives an online loading command. Therefore, logical devices may be loaded repeatedly before the board is powered on again. The effective program is the program last loaded before the board is powered on again.

In the embodiment described above, after the receiving module 61 receives an online loading command, the enabling/disabling module 62 disables the JTAG link of the board on which the logical device is located through the bus between the processor and the logical device, and enables the link between the I/O interface and the JTAG interface of the logical device; and the control module 63 controls the logical device through the bus so that the logical device is loaded online through the link between the I/O interface and the JTAG interface of the logical device. In this way, the logical device is loaded online without occupying any I/O interface or requiring addition of any I/O device. The processor provided in the foregoing embodiment is also applicable to loading logical devices online on a board that includes no processor but includes a bus interface.

FIG. 7 is a schematic structure diagram of a system for loading a logical device online according to an embodiment of the present invention. As shown in FIG. 7, the system for loading a logical device online includes a processor 71 and a logical device 72. The I/O interface of the logical device 72 is looped back to the JTAG interface of the logical device 72, and the logical device 72 is connected with the processor 71 through the bus. The bus is a control bus or another type of bus.

The processor 71 receives the online loading command, disables the JTAG link of the board on which the logical device is located 72 through the bus between the processor 71 and the logical device 72 according to the online loading command, and enables the link between the I/O interface and the JTAG interface of the logical device 72. The processor 71 controls the logical device 72 through the bus so that the logical device 72 is loaded online through the link between the I/O interface and the JTAG interface of the logical device 72. Specifically, the processor 71 may be the processor shown in FIG. 5 or FIG. 6.

The logical device 72 is loaded online through the link between the I/O interface and the JTAG interface of the logical device 72 under control of the processor 71.

The logical device 72 in this embodiment may be a programmable logical device such as CPLD.

In this embodiment, the I/O interface of the logical device 72 is connected with the JTAG interface of the logical device 72, and the processor 71 controls the logical device 72 through the bus between the processor 71 and the logical device 72 so that the logical device 72 is loaded online through the link between the I/O interface and the JTAG interface of the logical device 72. In this way, the logical device is loaded online without occupying any I/O interface or requiring addition of any I/O device.

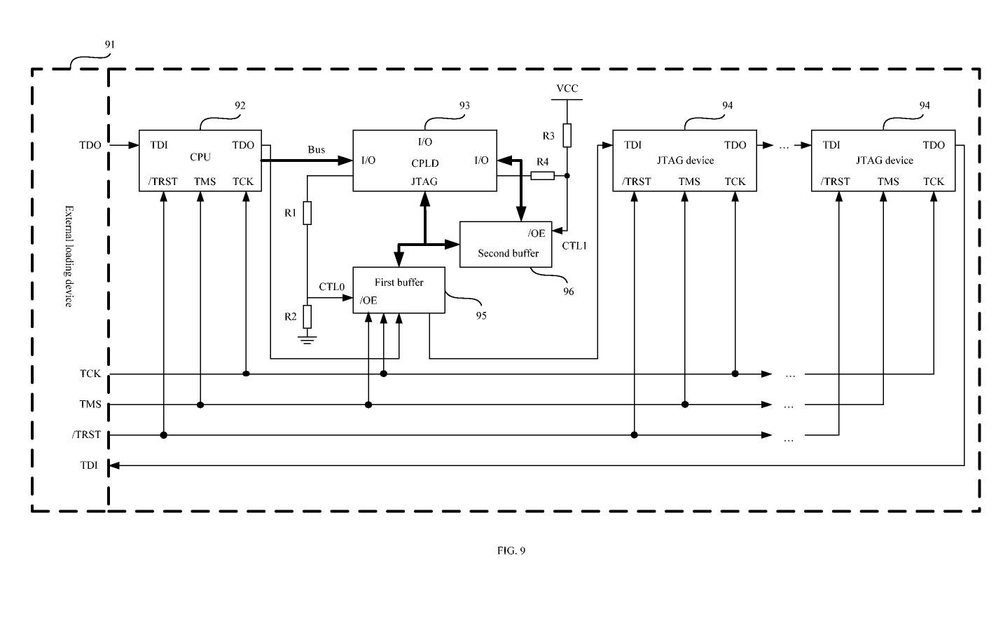

FIG. 8 is a schematic structure diagram of a system for loading a logical device online according to another embodiment of the present invention. As shown in FIG. 8, the system for loading a logical device online includes a processor 81, a logical device 82, and an external loading device 83. The I/O interface of the logical device 82 is looped back to the JTAG interface of the logical device 82, and the logical device 82 is connected with the processor 81 through the bus. The bus is a control bus or another type of bus.

The processor 81 receives an online loading command, disables a JTAG link of a board on which the logical device is located 82 through a bus between the processor 81 and the logical device 82 according to the online loading command, and enables a link between an I/O interface and a JTAG interface of the logical device 82; and controls the logical device 82 through the bus so that the logical device 82 is loaded online through the link between the I/O interface and the JTAG interface of the logical device 82. Specifically, the processor 81 may be the processor shown in FIG. 5 or FIG. 6.

The logical device 82 is loaded online through the link between the I/O interface and the JTAG interface of the logical device 82 under control of the processor 81.

The logical device 82 in this embodiment may be a programmable logical device such as CPLD.

The external loading device 83 may use a JTAG loading wire to load the logical device 82.

In this embodiment, the I/O interface of the logical device 82 is connected with the JTAG interface of the logical device 82, and the processor 81 controls the logical device 82 through the bus between the processor 81 and the logical device 82 so that the logical device 82 is loaded online through the link between the I/O interface and the JTAG interface of the logical device 82. In this way, the logical device is loaded online without occupying any I/O interface or requiring addition of any I/O device.

Assuming that the processor is a CPU and the logical device is a CPLD, the following describes the structure of a system for loading a logical device online according to an embodiment of the present invention.

FIG. 9 is a schematic structure diagram of a system for loading a logical device online according to a preferred embodiment of the present invention. As shown in FIG. 9, the system may include an external loading device 91, a CPU 92, a CPLD 93, and a JTAG device 94. The CPU 92, the CPLD 93, and the JTAG device 94 are located on the same board. The I/O interface of the CPLD 93 is looped back to the JTAG interface of the CPLD 93, and the CPU 92 is connected with the CPLD 93 through a bus. The bus is a control bus or another type of bus. The system in embodiment may further include a first buffer 95 and a second buffer 96. The first buffer 95 is located between the JTAG interface and the JTAG device 94 of the CPLD 93, and the second buffer 96 is located between the JTAG interface and the I/O interface of the CPLD 93. The system structure shown in FIG. 9 is only an exemplary structure of the system for loading a logical device online in this embodiment. This embodiment is not limited to that structure. The system for loading a logical device online may include no JTAG device 94. In this case, the first buffer 95 is located between the JTAG interface of the CPLD 93 and the external loading device 91.

After a board is processed, no program is loaded in the CPLD 93, and each I/O interface is in one of the three states: input, output, and high ohm. In this case, through a default pull-down resistor R2 and a default pull-up resistor R3 in the circuit, the CPLD 93 is connected as a JTAG device in the JTAG link of the board. The JTAG link includes a CPLD 93 and at least one JTAG device 94. In this case, the external loading device 91 may use a JTAG loading wire to load the CPLD 93 initially. For example, with a JTAG download cable being connected to a JTAG socket, the external loading device 91 loads the CPLD 93 initially. After the initial loading, the logical functions of the CPLD 93 run normally. By default, the register of the CPLD 93 controls the I/O interfaces CTL0 and CTL1 to enable the first buffer 95 on the JTAG link of the board that includes the CPLD 93 and disable the second buffer 96 on the link between the I/O interface and the JTAG interface of the CPLD 93. In this way, the register of the CPLD 93 enables the JTAG link of the board that includes the CPLD 93 and disables the link between the I/O interface and the JTAG interface of the CPLD 93. At this time, the external loading device 91 may use the JTAG loading wire to load the CPLD 93 for a second time.

After receiving the online loading command, the CPU 92 disables the JTAG link of the board that includes the CPLD 93 through the bus between the CPU 92 and the CPLD 93, and enables the link between the I/O interface and the JTAG interface of the CPLD 93. Specifically, the CPU 92 enables the first buffer 95 on the JTAG link of the board that includes the CPLD 93 through the bus, and disables the second buffer 96 on the link between the I/O interface and the JTAG interface of the CPLD. Afterward, the CPU 92 controls the CPLD 93 through the bus so that the CPLD 93 is loaded online through the link between the I/O interface and the JTAG interface of the CPLD 93. Upon completion of the loading, CPU 92 controls the I/O interfaces CTL0 and CTL1 of the CPLD 93 to restore the default state of the first buffer 95 and the second buffer 96, namely, to enable the first buffer 95 and disable the second buffer 96. At this time, the new program has been loaded onto an on-chip flash memory of the CPLD 93, and the CPU 92 can exercise control to power on the board that includes the CPLD 93 at any proper time and update the logics of the CPLD 93.

To prevent control conflict between two buffers caused by incorrect programming, two resistors R1 and R4 may be concatenated at the control I/O output side. In this way, the two buffers can be disconnected when they incur control conflict, and the CPLD 93 is connected with the JTAG link of the board to get loaded again. Alternatively, an I/O output and a Not-gate may be used to control the two buffers so that the JTAG link of the board is mutually exclusive of the link between the I/O interface and the JTAG interface of the CPLD. The foregoing provides only two modes of implementing mutual exclusiveness of the link. This embodiment is not limited to that. Any mode that implements mutual exclusiveness between the JTAG link of the board and the link from the I/O interface to the JTAG interface of the CPLD shall fall within the protection scope of the present invention.

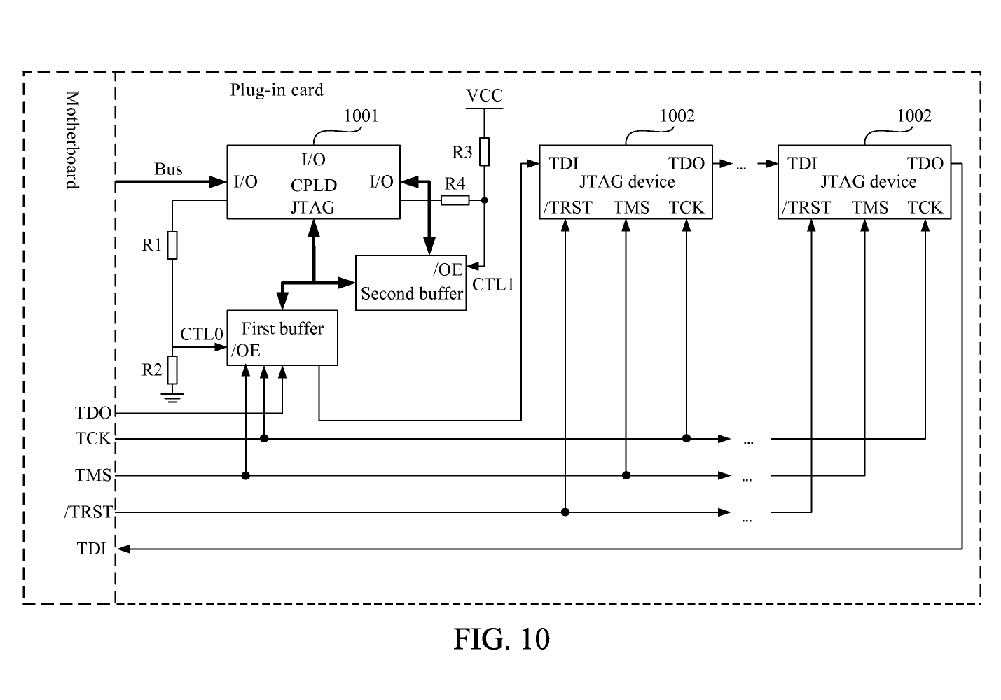

FIG. 10 is a schematic structure diagram of a system for loading a logical device online according to another preferred embodiment of the present invention. As shown in FIG. 10, the system may include a CPLD 1001 and a JTAG device 1002. The CPLD 1001 and the JTAG device 1002 are located on the same plug-in bard; the I/O interface of the CPLD 1001 is looped back to the JTAG interface of the CPLD 1001, and the CPLD 1001 is connected with the CPU of the motherboard through a bus. The bus is a control bus or another type of bus.

FIG. 10 shows a system structure designed for plug-in cards. In the case that the interface between the motherboard and the plug-in card connector is fixed and no free I/O interface is available, the system shown in FIG. 10 also supports the two links (JTAG link of the board, and the link between the I/O interface and the JTAG interface of the CPLD 1001), and implements the two basic functions (linking of the JTAG device on the plug-in card, and online loading of the CPLD). The detailed implementation process is similar to the process shown in FIG. 9, and is not repeated here any further.

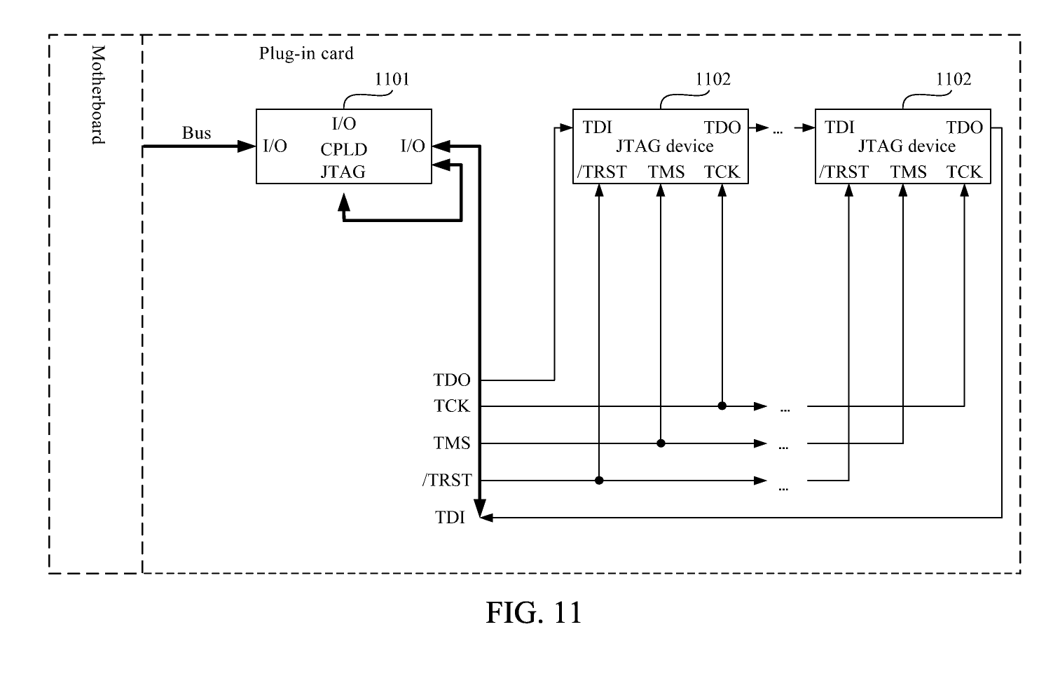

FIG. 11 is a schematic structure diagram of a system for loading a logical device online according to another preferred embodiment of the present invention. As shown in FIG. 11, the system may include a CPLD 1101 and a JTAG device 1102. The CPLD 1101 and the JTAG device 1102 are located on the same plug-in bard; the I/O interface of the CPLD 1101 is looped back to the JTAG interface of the CPLD 1101, and the CPLD 1101 is connected with the CPU of the motherboard through a bus. The bus is a control bus or another type of bus.

The system structure shown in FIG. 11 is applicable to the scenario with neither free I/O interface from the motherboard to the plug-in card nor JTAG interface. In this case, the buffers are cancelled because mutual exclusiveness between two JTAG links never occurs. The CPU controls different I/O interfaces of the CPLD 1101 through a bus to simulate two JTAG links. One JTAG link is located between the I/O interface and the JTAG interface of the CPLD 1101, and designed to implement online loading of the CPLD 1101; and the other is the JTAG link of the board, and includes the CPLD 1101 and the JTAG device 1102.

In the system shown in FIG. 11, the process of online loading of the CPLD 1101 is similar to the process shown in FIG. 9, and is not repeated here any further.

It is understandable to those skilled in the art that the accompanying drawings are only schematic diagrams of preferred embodiments, and the modules or processes in the accompanying drawings are not mandatory for implementing the present invention.

It is understandable to those skilled in the art that the modules in an apparatus provided in an embodiment of the present invention may be distributed in the apparatus in the way described, or may be located in one or more apparatuses different from the apparatus described herein. The modules may be combined into one, or split into submodules.

Finally, it should be noted that the above embodiments are merely provided for describing the technical solutions of the present invention, but not intended to limit the present invention. It is apparent that persons skilled in the art can make various modifications and variations to the invention without departing from the spirit and scope of the invention. The present invention is intended to cover the modifications and variations provided that they fall in the scope of protection defined by the following claims or their equivalents.

What is claimed is:

1. A method for loading a logical device online, comprising:
receiving an online loading command;
disabling a Joint Test Action Group (JTAG) link of a board on which the logical device is located through a bus between a processor and the logical device according to the online loading command, and enabling a link between an input/output (I/O) interface and a JTAG interface of the logical device through the bus according to the online loading command; and
controlling the logical device through the bus so that the logical device is loaded online through the link between the I/O interface and the JTAG interface of the logical device.

2. The method according to claim 1, further comprising:
upon completion of the online loading, enabling the JTAG link of the board on which the logical device is located through the bus, and disabling the link between the I/O interface and the JTAG interface of the logical device; and recording an online loading completion event; and
re-powering the board on which the logical device is located and updating the logic of the logical device through the bus.

3. The method according to claim 1, wherein:
after receiving an online loading command, the method further comprises: clearing the online loading completion event.

4. The method according to claim 1, wherein:
the disabling of the JTAG link of the board on which the logical device is located through the bus between the processor and the logical device, and the enabling of the link between the I/O interface and the JTAG interface of the logical device, comprise:
disabling a first buffer on the JTAG link of the board on which the logical device is located through the bus, and enabling a second buffer on the link between the I/O interface and the JTAG interface of the logical device.

5. The method according to claim 2, wherein:
the enabling of the JTAG link of the board on which the logical device is located through the bus, and the disabling of the link between the I/O interface and the JTAG interface of the logical device, comprise:
enabling a first buffer on the JTAG link of the board on which the logical device is located through the bus, and disabling a second buffer on the link between the I/O interface and the JTAG interface of the logical device.

6. A processor, comprising:
a receiving module, configured to receive an online loading command;
an enabling/disabling module, configured to disable a Joint Test Action Group (JTAG) link of a board on which a logical device is located through a bus between the processor and the logical device according to the online loading command received by the receiving module, and enable a link between an input/output (I/O) interface and a JTAG interface of the logical device through the bus according to the online loading command; and
a control module, configured to control the logical device through the bus so that the logical device is loaded online through the link between the I/O interface and the JTAG interface of the logical device.

7. The processor according to claim 6, wherein:
the enabling/disabling module is further configured to enable the JTAG link of the board on which the logical device is located through the bus, and disable the link between the I/O interface and the JTAG interface of the logical device after completion of the online loading; and
the control module is further configured to re-power the board on which the logical device is located and update logic of the logical device after completion of the online loading through the bus.

8. The processor according to claim 6, further comprising:
a recording module, configured to record an online loading completion event upon completion of the online loading;
a clearing module, configured to clear the online loading completion event recorded by the recording module after receipt of the online loading command by the receiving module.

9. The processor according to claim 6, wherein:
the enabling/disabling module disables a first buffer on the JTAG link of the board on which the logical device is located through the bus, and enables a second buffer on the link between the I/O interface and the JTAG interface of the logical device.

10. The processor according to claim 7, wherein:
after the online loading is complete, the enabling/disabling module disables a second buffer on the link between the I/O interface and the JTAG interface of the logical device through the bus, and enables a first buffer on the JTAG link of the board on which the logical device is located.

11. A system for loading a logical device online, comprising:
a processor, configured to: receive an online loading command, disable a Joint Test Action Group (JTAG) link of a board on which the logical device is located through a bus between the processor and the logical device according to the online loading command, and enable a link between an input/output (I/O) interface and a JTAG interface of the logical device through the bus according to the online loading command; and control the logical device through the bus so that the logical device is loaded online through the link between the I/O interface and the JTAG interface of the logical device; and
a logical device, configured to be loaded online through the link between the I/O interface and the JTAG interface of the logical device under control of the processor.

12. The system according to claim 11, further comprising:
an external loading device, configured to load the logical device online through a JTAG loading wire.
